(19) United States
(12) Patent Application Publication
(10) Pub. No.: US 2022/0384330 A1
(43) Pub. Date: Dec. 1, 2022

(54) HIGH SPEED BRIDGE BETWEEN A PACKAGE AND A COMPONENT

(71) Applicant: Intel Corporation, Santa Clara, CA (US)

(72) Inventor: Telesphor KAMGAING, Chandler, AZ (US)

(21) Appl. No.: 17/334,178

(22) Filed: May 28, 2021

(51) Int. Cl. H01L 23/498; H01L 23/00

(52) U.S. Cl. CPC H01L 23/49866; H01L 23/49816; H01L 23/49822; H01L 24/20; H01L 2224/215; H01L 2924/12042; H01L 2924/15311; H01L 2924/15788

(57) ABSTRACT

Embodiments described herein may be related to apparatuses, processes, and techniques related to a vertical high-speed bridge placed within a BGA field of a microelectronic package. In embodiments, the bridge is used for high-speed signaling and may include plated through hole vias that are at a smaller pitch than the pitch of the BGA field. In embodiments, the vertical high-speed bridge may be constructed from a glass wafer or a glass panel using a laser-assisted etching of glass interconnects process. Other embodiments may be described and/or claimed.

### FIELD

Embodiments of the present disclosure generally relate to the field of semiconductor packaging, and in particular to input/output (I/O) couplings between components.

### BACKGROUND

Continued growth in virtual machines and cloud computing will continue to increase the demand for high-speed I/O between packages and substrates.

### BRIEF DESCRIPTION OF THE DRAWINGS

FIG. 1 illustrates multiple examples of laser-assisted etching of glass interconnects processes, in accordance with embodiments.

FIG. 2 illustrates a legacy implementation of electrical interconnects between a package and a substrate using a ball grid array (BGA) second level interconnect.

FIG. 3 illustrates a side view of an assembly that includes a bridge to provide high density I/O connections between a package and a substrate, in accordance with embodiments.

FIG. 4 illustrates a top down view of a bridge, in accordance with embodiments.

FIG. 5 illustrates a side view of an assembly that includes a bridge to provide high density I/O connections between a package that includes a glass core and a substrate, in accordance with embodiments.

FIG. 6 illustrates a side view of an assembly that includes a bridge that extends into a buildup layer cavity of a package where the package includes a partial glass core, in accordance with embodiments.

FIG. 7 illustrates a side view of an assembly that includes a bridge that extends into a buildup layer cavity of the package where the package includes a full glass core, in accordance with embodiments.

FIG. 8 illustrates an example process for creating an apparatus that includes a package and a substrate that are coupled with a bridge, in accordance with embodiments.

FIG. 9 schematically illustrates a computing device, in accordance with embodiments.

### DETAILED DESCRIPTION

Embodiments described herein may be related to apparatuses, processes, and techniques for providing a vertical high-speed bridge within a BGA field of a microelectronic package. In embodiments, the bridge may be used for high-speed signaling, in contrast to legacy interconnects that are used, for example, for low-frequency signaling and power delivery only. In embodiments, the vertical high-speed bridge may be constructed from a glass wafer or a glass panel.

One or more laser sources followed by wet-etching may be used to create through hole vias or trenches into the glass panel or glass wafer. Using these laser techniques, vias may be created with a small diameter, for example on the order of less than 10 μm, and may be spaced with a pitch on the order of 50 μm or less. Other vias may be created with different diameter sizes. These vias may be later plated for filled to create electrical pathways through the bridge. These techniques may be used to create vias in the glass wafer or panel that have high aspects ratios, for example 40:1 or 50:1. Because of the fine pitch of the vias, more signals may be put through the BGA field at a higher density and may expand the frequency range resulting in a higher bandwidth communications. In addition, these techniques may reduce or eliminate impedance mismatch, which in legacy implementations may limit the frequency bandwidth of signals transmitted through the package BGA interface.

In embodiments, a vertical bridge, which may also be referred to as a bridge, may be inserted between a package and a substrate at the second level interconnect. The bridge, which can be silicon or glass-based, may have fine pitch vertical interconnects, which may be referred to as through substrate vias (TSV) and through substrate planes (TSP), which may be used for the high-speed signaling. The second level interconnect may further include BGA balls that are spaced at a wider pitch than the through hole vias of the vertical bridge. These BGA balls may be used for power delivery and low frequency signaling, where the bridge may be used for higher frequency signaling. The pitch of the BGA balls may be in the order of 300 μm to 1000 μm, whereas the pitch of vias on the vertical bridge may be in the order of 50 μm to 200 μm.

In future package implementations, platform level implementations of high-speed interconnects will be important for future high-performance microelectronic systems. As the number of dies on a platform increases, it becomes necessary to use multiple packages to accommodate all of the dies. Placing high-speed dies on those different packages requires that high-speed links are provided into and out of the various packages. In legacy implementations, two main aspects of the packages may be limiting bandwidth for such links. The first bandwidth limitation may result from large pitch vias within a package core that may introduce broadband impedance mismatch. The second bandwidth limitation may result from wide pitch second-level interconnects, e.g. BGAs, that exhibit high mismatch as well as enhanced the signal coupling and degradation.

In legacy implementations using a patch-on-interposer, a BGA pitch may work fine, and therefore the effect of bandwidth limitations using a BGA may be less pronounced. However, for BGA assemblies on a printed circuit board, the large bump heights and pitches of a second level interconnect (SLI) amplifies performance problems. In embodiments, using laser-assisted etching of glass interconnects, which may be referred to as “LEGIT” techniques, described herein to produce high density vias may help reduce the impedance mismatch and signal coupling at the core of a package. In embodiments, for ultimate integration of components, having a very fine pitch SLI may be critical for both bandwidth and signal density for system operation. Embodiments described herein include a bridge to facilitate signal integrity at the SLI.

In legacy implementations, with the exception of very small form factor packages where bandwidth density is not an issue, microelectronic packages use large pitch SLI between packages and printed circuit boards. These legacy implementations result in a low bandwidth density, both in terms of frequency limitation and a high BGA pitch, signal leakage, and potential package size increases due to additional BGAs that may be required for shielding at large pitches.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

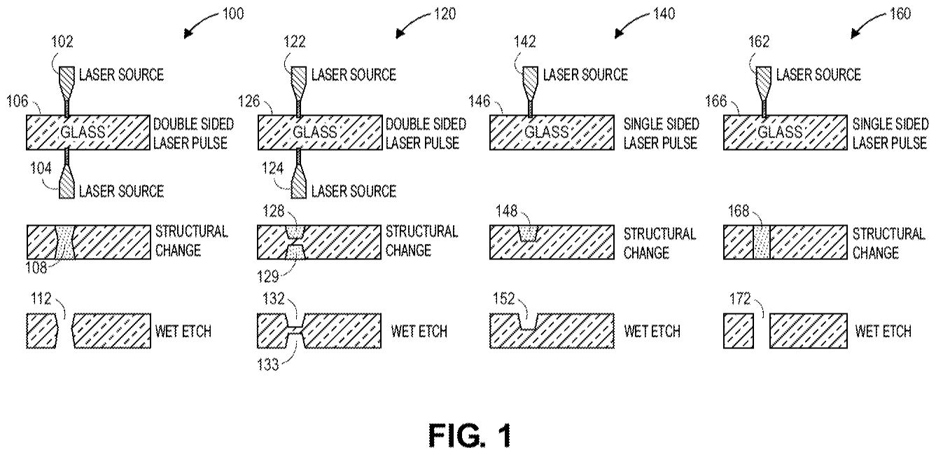

FIG. 1 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 100 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 112 is created by laser pulses from two laser sources 102, 104 on opposite sides of a glass wafer 106. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 102, 104 are applied perpendicularly to the glass wafer 106 to induce a morphological change 108, which may also be referred to as a structural change, in the glass that encounters the laser pulses. This morphological change 108 includes changes in the molecular structure of the glass to make it easier to etch out (remove a portion of the glass). In embodiments, a wet etch process may be used.

Diagram 120 shows a high level process flow for a double blind shape. A double blind shape 132, 133 may be created by laser pulses from two laser sources 122, 124, which may be similar to laser sources 102, 104, that are on opposite sides of the glass wafer 126, which may be similar to glass wafer 106. In this example, adjustments may be made in the laser pulse energy and/or the laser pulse exposure time from the two laser sources 122, 124. As a result, morphological changes 128, 129 in the glass 126 may result, with these changes making it easier to etch out portions of the glass. In embodiments, a wet etch process may be used.

Diagram 140 shows a high level process flow for a single-blind shape, which may also be referred to as a trench. In this example, a single laser source 142 delivers a laser pulse to the glass wafer 146 to create a morphological change 148 in the glass 146. As described above, these morphological changes make it easier to etch out a portion of the glass 152. In embodiments, a wet etch process may be used.

Diagram 160 shows a high level process flow for a through via shape. In this example, a single laser source 162 applies a laser pulse to the glass 166 to create a morphological change 168 in the glass 166, with the change making it easier to etch out a portion of the glass 172. As shown here, the laser pulse energy and/or laser pulse exposure time from the laser source 162 has been adjusted to create an etched out portion 172 that extends entirely through the glass 166.

With respect to FIG. 1, although embodiments show laser sources 102, 104, 122, 124, 142, 162 as perpendicular to a surface of the glass 106, 126, 146, 166, in embodiments, the laser sources may be positioned at an angle to the surface of the glass, with pulse energy and/or pulse exposure time variations in order to cause a diagonal via or a trench, or to shape the via, such as 112, 172, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 1, through hole vias 112, 172 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

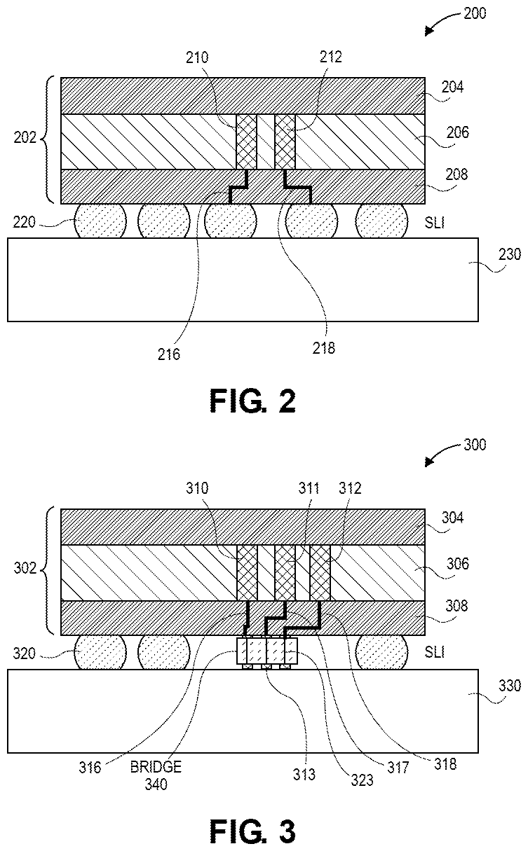

FIG. 2 illustrates a legacy implementation of electrical interconnects between a package and a substrate using a BGA second level interconnect. Legacy assembly 200 includes a package 202 that may include a first buildup layer 204, a core 206, and a second buildup layer 208. In embodiments, each of the build-up layers 204 and 208 may be made out of several build-up, metal and via layers. For example, build-up layers 204, 208 may have up to 10 layers in a server product. The core 206 may be a CCL core, and include a number of plated through holes (PTH) 210, 212 that may be used to carry signals from the first buildup layer 204 to the second buildup layer 208. In implementations, electrical connectors 216, 218 may electrically couple the plated through holes 210, 212 with one or more BGA balls 220 to provide an electrical and/or physical coupling with a substrate 230. In implementations, the plated through holes 210, 212 may have a 400 μm pitch, and the BGA balls 220 may have a 600 μm or larger pitch, In embodiments, the substrate 230 may be a printed circuit board (PCB), a die, or another package. In embodiments, the BGA balls 220 may be a SLI.

The first buildup layer 204 and the second buildup layer 208 may include a number of layers, for example 10 layers or more. In this legacy example, because the pitch of the plated through holes 210, 212 is narrower than the pitch of the BGA balls 220, the electrical connectors 216, 218 have to fanout to electrically couple with the appropriate balls 220 in order to make an appropriate electrical connection on the substrate 230.

A disadvantage of this legacy approach is that fanning out to the BGA 220 layer means that signal frequencies will not be able to go very high. As a result, these legacy implementations may be limited to 56 GHz, resulting in a limit of 254 Gb per second signaling. In implementations, with increased pitch comes an increased potential for impedance mismatch that also limits how high signal frequency can go. In implementations, designers may want a certain impedance, for example 50 Ohms for the electrical connections between the package 202 and the substrate 230. However, with different buildup layers and fanout of the connections described above that increase spacing between the signal and the reference, signal to ground capacitance may change from package to BGA or from layer to layer, resulting in a different impedance near the substrate 230 versus at the top buildup layer 204. In addition, there may be a signal reflection. As the frequency of the signal goes up, this reflection becomes greater and is very challenging to control.

FIG. 3 illustrates a side view of an assembly that includes a bridge to provide high density I/O connections between a package and a substrate, in accordance with embodiments. Assembly 300 shows a package 302 that may include a first buildup layer 304, a core 306, and a second buildup layer 308, which may be similar to package 202, first buildup layer 204, core 206, and second buildup layer 208 of FIG. 2. The core 306 may be a CCL core, and include a number of plated through holes (PTH) 310, 311, 312 that may be used to carry signals from the first buildup layer 304 to the second buildup layer 308. In implementations, electrical connectors 316, 317, 318 may couple, respectively, the plated through holes 310, 311, 312 with a bridge 340. The bridge may be at a same level of a BGA 320, which may be similar to BGA 220 of FIG. 2. In embodiments, the bridge may be at the SLI level. Furthermore, the bridge may be electrically coupled with the substrate 330, which may be similar to substrate 230 of FIG. 2.

In embodiments, the bridge 340 may be a glass wafer, such as glass wafer 106, 166 of FIG. 1. The bridge 340 may include a plurality of through substrate vias (TSV) 323 that may be created using techniques described with respect to FIG. 1, to provide electrical coupling between the electrical connectors 316, 317, 318 and locations on the substrate 330. In embodiments, electrical contacts 313 may be placed on a top side and/or a bottom side of the bridge 340 to facilitate electrical coupling. The pitches of the plurality of TSV 323 may be significantly smaller than the pitches of the BGA balls 320. For example, pitches of the plurality of TSV 323 may be on the order of 50 μm, whereas the pitches of the plurality of the BGA balls 320 may be on the order of 500 μm. In embodiments, multiple bridges 340 may be used, and may be placed in various locations within the SLI layer.

In embodiments, the bridge 340 may take any shape, and may not necessarily be rectangular as shown in FIG. 3. In embodiments, the bridge 340 may take an irregular shape depending upon the electrical connectivity requirements of the substrate 330, or the positioning of the BGA balls 320 that couple the package 302 with the substrate 330. In embodiments, the height of the bridge 340 and electrical contacts 313 may be less than the height of the solder ball SLI before collapse. In embodiments, a thickness may be a few microns more than the BGA 320 collapse height. In embodiments, the bridge 340 may be used to control the gap between package 302 and substrate 330 after assembly.

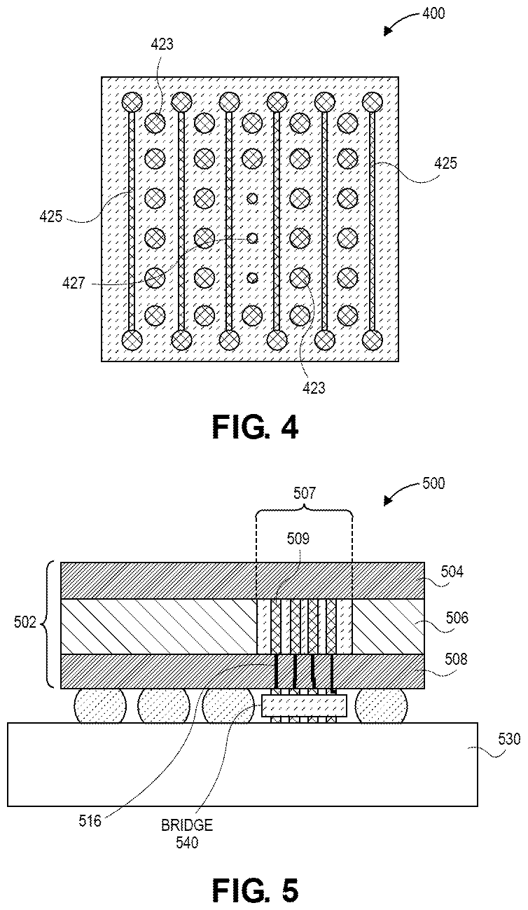

FIG. 4 illustrates a top down view of a bridge, in accordance with embodiments. Bridge 400, which may be similar to bridge 340 of FIG. 3, is shown in a top-down view. In embodiments, bridge 400 may also be an example of a top-down view of a glass core, such as glass core 507 of FIG. 5. Bridge 400 may include a plurality of TSV 423 that may electrically couple the top side of the bridge 400 with the bottom side of the bridge 400. In embodiments, the TSV 423 may also include electrical connectors, for example electrical connectors 313 of FIG. 3. In embodiments, these electrical connectors, or bumps, may be plated metallizations, or may be solder attachments.

In some embodiments, the bridge 400 may include different diameter sizes, for example TSV 423, 427, and/or different materials used for metallization, depending upon how that particular TSV 423, 427 is to be used. For example, a signal may use a smaller diameter size, where a ground or a power connection may require a larger diameter size. In addition, trench routings may be used on the top or bottom surfaces of the bridge 400, for example trench routing 425. These trench routing 425 may also be used to couple a plurality of TSV 423 in order to support a higher amperage connection, or may be used to route signals, for example from an electrical connection 317 to a different location on the substrate 330 with respect to FIG. 3. In embodiments, the material of the bridge 400 may be glass or silicon.

FIG. 5 illustrates a side view of an assembly that includes a bridge to provide high density I/O connections between a package that includes a glass core and a substrate, in accordance with embodiments. Assembly 500, which may be similar to assembly 300, shows a package 502 that may include a first buildup layer 504, a core 506, and a second buildup layer 508, which may be similar to package 302, first buildup layer 304, core 306, and second buildup layer 308 of FIG. 3. The core 506 may be a CCL core that also includes a partial glass core 507. In embodiments, the partial glass core 507 may be made using techniques described with respect to FIG. 1.

In embodiments, the partial glass core 507 may include plated through holes (PTH) 509 used to carry signals from the first buildup layer 504 to the second buildup layer 508. In implementations, electrical connectors 516, which may be similar to electrical connectors 316, 317, 318 of FIG. 3, may couple, respectively, the plated through holes 509 with a bridge 540, which may be similar to bridge 340 of FIG. 3. The bridge 540 may be at the SLI level. Furthermore, the bridge 540 may be electrically coupled with the substrate 530, which may be similar to substrate 330 of FIG. 3.

The plated through holes 509 within the glass core 507 may have a high density pitch that is substantially smaller than PTH 310, 311, 312 of FIG. 3, which are implemented within a CCL core 306. As a result, in embodiments, assembly 500 may enable not only high density interconnections, but also interconnects that may be suitable for serial/deserialization (SerDes) integration beyond 448 Gbps per interconnect. As shown, the I/O pitch on the bridge 540 is comparable to the I/O pitch within the glass core 507 and the pitch of the electrical connections 516 within the second buildup layer 508. Thus, this embodiment allows for a tight pitch that goes straight down from the first buildup layer 504 to the substrate 530. Note that in other embodiments, there may be multiple glass cores 507 and multiple bridges 540. This may result in reduced discontinuity, leading to higher frequency bandwidth as well as a reduction in the substrate area used for high-speed signaling links.

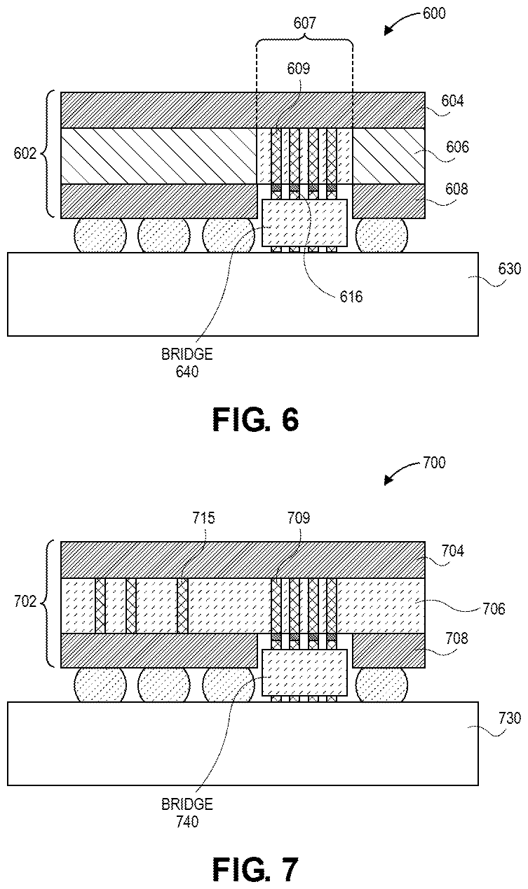

FIG. 6 illustrates a side view of an assembly that includes a bridge that extends into a buildup layer cavity of a package where the package includes a partial glass core, in accordance with embodiments. Assembly 600, which may be similar to assembly 500, includes a package 602 that may include a first buildup layer 604, a core 606, and a second buildup layer 608, which may be similar to package 502, first buildup layer 504, core 506, and second buildup layer 508 of FIG. 5. The core 606 may be a CCL core that also includes a partial glass core 607, which may be similar to partial glass core 507 of FIG. 5. In embodiments, the partial glass core 607 may be made using techniques described with respect to FIG. 1.

In embodiments, the bridge 640 may be recessed within the second buildup layer 608, and the top of the bridge 640 may be directly electrically coupled with PTH 609, which may be similar to PTH 509 of FIG. 5. The bottom of bridge 640 may be directly electrically coupled with the substrate 630, which may be similar to substrate 530 of FIG. 5. The PTH 609 may be electrically coupled with the bridge 640 using electrical connections 616, which may be similar to electrical connectors 516 of FIG. 5. Note that the connections on the top side and/or bottom side of the bridge 640 may be solder connections or metal bonding, such as precision metal bonding connections.

FIG. 7 illustrates a side view that includes a bridge that extends into a buildup layer cavity of the package where the package includes a full glass core, in accordance with embodiments. Assembly 700, which may be similar to assembly 600, shows a package 702 that may include a first buildup layer 704, a core 706, and a second buildup layer 708, which may be similar to package 602, first buildup layer 604, core 606, and second buildup layer 608 of FIG. 6. The core 706 may be a glass core, which may be similar to partial glass core 607 of FIG. 6. In embodiments, the glass core 706 may be made using techniques described with respect to FIG. 1.

In embodiments, the bridge 740 may be recessed within the second buildup layer 708. In embodiments, the top of the bridge 740 may be directly electrically coupled with PTH 709, which may be similar to PTH 609 of FIG. 6. The bottom of bridge 740 may be directly electrically coupled with the substrate 730, which may be similar to substrate 630 of FIG. 6. In contrast with assembly 600, the entire core 706 may be glass, and may include other PTH 715 to provide electrical couplings between the first buildup layer 704 and the second buildup layer 708. Note that the connections on the top side and/or bottom side of the bridge 740 may be solder connections or metal bonding, such as precision metal bonding connections.

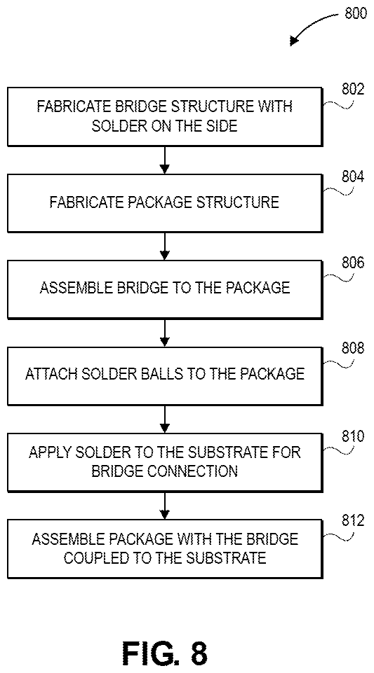

FIG. 8 illustrates an example process for creating an apparatus that includes a package and a substrate that are coupled with a bridge, in accordance with embodiments. Process 800 may be implemented using the processes, techniques, apparatus, and/or systems described with respect to FIGS. 1-7 herein.

At block 802, the process may include to fabricate a bridge structure. In embodiments, the bridge structure may be similar to bridge 340 of FIG. 3, bridge 400 of FIG. 4, bridge 540 of FIG. 5, bridge 640 of FIG. 6, or bridge 740 of FIG. 7. In embodiments, the fabrication of the bridge structure may be done according to the techniques described with respect to FIG. 1, in particular with respect to diagrams 100, 120, 140, and 160.

At block 804, the process may further include to fabricate a package structure. In embodiments, the package structure may be similar to package 302 of FIG. 3, package 502 of FIG. 5, package 602 of FIG. 6, or package 702 of FIG. 7.

At block 806, the process may further include to assemble the bridge to the package. In embodiments, the bridge and package may be assembled as shown with respect to FIGS. 3 and/or 5-7.

At block 808, the process may further include to attach solder balls to the package. In embodiments, the solder balls may be similar to solder balls 220 of FIG. 2, or 320 of FIG. 3.

At block 810, the process may further include to apply solder to the substrate for the bridge connection. In embodiments, the substrate may be similar to substrate 330 of FIG. 3, 530 of FIG. 5, 630 of FIG. 6, or 730 of FIG. 7, with solder to electrically and/or physically couple the bridge and solder balls

At block 812, the process may further include to assemble the package with the bridge coupled to the substrate. In embodiments, this may involve discrete attachments and solder reflow.

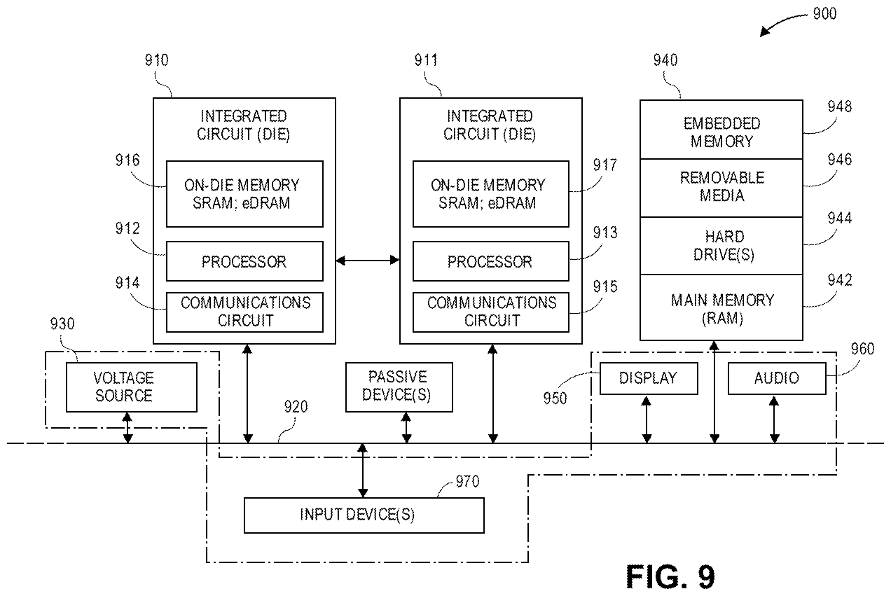

FIG. 9 schematically illustrates a computing device, in accordance with embodiments.

The computer system 900 (also referred to as the electronic system 900) as depicted can embody all or part of a high-speed bridge between a package and a component, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, all or part of a high-speed bridge between a package and a component, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including all or part of a high-speed bridge between a package and a component, according to any of the several disclosed embodiments and their equivalents, an electronic system, a computer system, one or more methods of fabricating an integrated circuit, and one or more methods of fabricating an electronic assembly that includes a package substrate implementing all or part of a high-speed bridge between a package and a component, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed processes used for a high-speed bridge between a package and a component embodiments and their equivalents. A foundation substrate may be included, as represented by the dashed line of FIG. 9. Passive devices may also be included, as is also depicted in FIG. 9.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 may be an apparatus comprising: a bridge having a first side and a second side opposite the first side, the first side of the bridge includes a plurality of electrical contacts that are electrically coupled, respectively, with a plurality of electrical contacts on the second side of the bridge using a plurality of electrical connectors within the bridge; wherein the plurality of electrical contacts on the first side of the bridge are to electrically couple with a plurality of contacts on a package; wherein the plurality of electrical contacts on the second side of the bridge are to electrically couple with a plurality of contacts on a substrate; wherein the bridge is positioned between the package and the substrate to electrically couple the package with the substrate; and wherein a pitch of the plurality of electrical connectors within the bridge is less than a pitch of a plurality of couplings outside the bridge that physically couple the package with the substrate.

Example 2 includes the apparatus of example 1, wherein the bridge is a glass bridge.

Example 3 includes the apparatus of example 2, wherein the plurality of electrical connectors of the bridge are, respectively, within a plurality of through hole vias in the glass bridge.

Example 4 includes the apparatus of example 3, wherein the plurality of electrical connectors are formed as plated through hole vias in the glass bridge.

Example 5 includes the apparatus of example 3, wherein at least some of the through hole vias have a pitch of less than 10 microns (μm).

Example 6 includes the apparatus of example 3, wherein at least some of the through hole vias have an aspect ratio of at least 20 to 1.

Example 7 includes the apparatus of example 3, wherein the through hole vias are created using a laser-assisted etching of glass interconnects (LEGIT) process.

Example 8 includes the apparatus of example 3, wherein at least one of the through hole vias is not circular.

Example 9 includes the apparatus of example 1, wherein the electrical connectors include a selected one of copper or gold.

Example 10 includes the apparatus of example 1, wherein the plurality of electrical contacts on the first side of the bridge or the plurality of electrical contacts on the second side of the bridge extend above a plane of the first side of the bridge or a plane of the second side of the bridge.

Example 11 includes the apparatus of example 1, wherein the plurality of couplings outside the bridge are ball grid array (BGA) couplings.

Example 12 includes the apparatus of any one of examples 1-11, wherein the bridge is positioned at a second level interconnect.

Example 13 is an apparatus comprising: a package having a first side and a second side opposite the first side; a substrate with a first side and a second side opposite the first side, the first side of the substrate physically coupled with the second side of the package with a ball grid array (BGA); a bridge having a first side and a second side opposite the first side, the first side of the bridge includes a plurality of electrical contacts that are electrically coupled, respectively, with a plurality of electrical contacts on the second side of the bridge using a plurality of electrical connectors; wherein the plurality of electrical contacts on the first side of the bridge are physically and electrically coupled with a plurality of contacts on a package; wherein the plurality of electrical contacts on the second side of the bridge are physically and electrically coupled with a plurality of contacts on a substrate; and wherein a distance of a pitch of the plurality of electrical contacts on the second side of the bridge is less than a distance of the pitch of the BGA.

Example 14 includes the apparatus of example 13, wherein the first side of the substrate is physically and electrically coupled with the second side of the package with the BGA.

Example 15 includes the apparatus of example 13, wherein the bridge is a glass bridge.

Example 16 includes the apparatus of example 15, wherein the plurality of electrical connectors of the bridge are, respectively, within a plurality of through hole vias in the glass bridge.

Example 17 includes the apparatus of example 16, wherein the plurality of electrical connectors are formed as plated through hole vias in the glass bridge.

Example 18 includes the apparatus of example 16, wherein at least some of the through hole vias have a pitch of less than 10 microns (μm).

Example 19 includes the apparatus of example 16, wherein at least some of the through hole vias have an aspect ratio of at least 50 to 1.

Example 20 includes the apparatus of any one of examples 13-19, wherein the bridge forms a high speed input/output (I/O) bridge.

Example 21 includes the apparatus of any one of examples 13-19, wherein the bridge is a silicon bridge.

What is claimed is:

1. An apparatus comprising:
a bridge having a first side and a second side opposite the first side, the first side of the bridge includes a plurality of electrical contacts that are electrically coupled, respectively, with a plurality of electrical contacts on the second side of the bridge using a plurality of electrical connectors within the bridge;
wherein the plurality of electrical contacts on the first side of the bridge are to electrically couple with a plurality of contacts on a package;
wherein the plurality of electrical contacts on the second side of the bridge are to electrically couple with a plurality of contacts on a substrate;
wherein the bridge is positioned between the package and the substrate to electrically couple the package with the substrate; and
wherein a pitch of the plurality of electrical connectors within the bridge is less than a pitch of a plurality of couplings outside the bridge that physically couple the package with the substrate.

2. The apparatus of claim 1, wherein the bridge is a glass bridge.

3. The apparatus of claim 2, wherein the plurality of electrical connectors of the bridge are, respectively, within a plurality of through hole vias in the glass bridge.

4. The apparatus of claim 3, wherein the plurality of electrical connectors are formed as plated through hole vias in the glass bridge.

5. The apparatus of claim 3, wherein at least some of the through hole vias have a pitch of less than 10 microns (μm).

6. The apparatus of claim 3, wherein at least some of the through hole vias have an aspect ratio of at least 20 to 1.

7. The apparatus of claim 3, wherein the through hole vias are created using a laser-assisted etching of glass interconnects (LEGIT) process.

8. The apparatus of claim 3, wherein at least one of the through hole vias is not circular.

9. The apparatus of claim 1, wherein the electrical connectors include a selected one of copper or gold.

10. The apparatus of claim 1, wherein the plurality of electrical contacts on the first side of the bridge or the plurality of electrical contacts on the second side of the bridge extend above a plane of the first side of the bridge or a plane of the second side of the bridge.

11. The apparatus of claim 1, wherein the plurality of couplings outside the bridge are ball grid array (BGA) couplings.

12. The apparatus of claim 1, wherein the bridge is positioned at a second level interconnect.

13. An apparatus comprising:
a package having a first side and a second side opposite the first side;
a substrate with a first side and a second side opposite the first side, the first side of the substrate physically coupled with the second side of the package with a ball grid array (BGA);
a bridge having a first side and a second side opposite the first side, the first side of the bridge includes a plurality of electrical contacts that are electrically coupled, respectively, with a plurality of electrical contacts on the second side of the bridge using a plurality of electrical connectors;
wherein the plurality of electrical contacts on the first side of the bridge are physically and electrically coupled with a plurality of contacts on a package;
wherein the plurality of electrical contacts on the second side of the bridge are physically and electrically coupled with a plurality of contacts on a substrate; and
wherein a distance of a pitch of the plurality of electrical contacts on the second side of the bridge is less than a distance of the pitch of the BGA.

14. The apparatus of claim 13, wherein the first side of the substrate is physically and electrically coupled with the second side of the package with the BGA.

15. The apparatus of claim 13, wherein the bridge is a glass bridge.

16. The apparatus of claim 15, wherein the plurality of electrical connectors of the bridge are, respectively, within a plurality of through hole vias in the glass bridge.

17. The apparatus of claim 16, wherein the plurality of electrical connectors are formed as plated through hole vias in the glass bridge.

18. The apparatus of claim 16, wherein at least some of the through hole vias have a pitch of less than 10 microns (μm).

19. The apparatus of claim 16, wherein at least some of the through hole vias have an aspect ratio of at least 50 to 1.

20. The apparatus of claim 13, wherein the bridge forms a high speed input/output (I/O) bridge.

21. The apparatus of claim 13, wherein the bridge is a silicon bridge.
